(19) United States
(12) Patent Application Publication
(10) Pub. No.: US 2023/0411229 A1
(43) Pub. Date: Dec. 21, 2023

(54) SEMICONDUCTOR DEVICE

(71) Applicant: FUJI ELECTRIC CO., LTD., Kawasaki-shi (JP)

(72) Inventors: Yuko NAKAMATA, Matsumoto-city (JP); Takamitsu YOSHIHARA, Takasaki-city (JP); Yuta TAMAI, Matsumoto-city (JP)

(73) Assignee: FUJI ELECTRIC CO., LTD., Kawasaki-shi (JP)

(21) Appl. No.: 18/309,351

(22) Filed: Apr. 28, 2023

(30) Foreign Application Priority Data
Jun. 20, 2022 (JP) 2022-099050

(51) Int. Cl. H01L 23/08; H01L 23/049; H01L 23/31; H01L 23/373; H01L 21/48

(52) U.S. Cl. CPC H01L 23/08; H01L 23/049; H01L 23/3142; H01L 23/3735; H01L 21/4817

(57) ABSTRACT

A semiconductor device in which delamination between a casing including polyphenylene sulfide with an inorganic filler and a sealing material can be suppressed. A semiconductor device including a casing 16 including an inorganic filler in a matrix including polyphenylene sulfide; a semiconductor element 11 mounted on a laminated substrate 12; and a sealing material 20 sealing the semiconductor element, wherein the inorganic filler is exposed from the matrix on a surface F of the casing 16 facing the sealing material.

### CROSS-REFERENCE TO RELATED APPLICATION

This application claims priority from Japanese Patent Application No. 2022-99050, filed on Jun. 20, 2022, which is incorporated herein by reference in their entirety.

### BACKGROUND OF THE INVENTION

### Field of the Invention

The present invention relates to a semiconductor device. The present invention particularly relates to a semiconductor device having high reliability in which stress concentration and moisture entry are prevented.

### Description of Related Art

Power semiconductor modules are widely applied in fields in which efficient power conversion is required. The application range extends to the field of power electronics, for example, industrial equipment, electric cars, and home electric appliances. These power semiconductor modules contain a switching element and a diode, and a Si (silicon) semiconductor or a SiC (silicon carbide) semiconductor is used for the element.

A power semiconductor module is manufactured by sealing a chip including a semiconductor element and an electrically conductive connecting member such as a lead frame connected to the chip with an insulating resin sealing material. The resin sealing material includes a thermosetting resin and an inorganic filler as main components.

As one example of the power semiconductor module, a semiconductor device in which a semiconductor element mounted on a laminated substrate, and an electrically conductive connecting member are sealed with a thermosetting resin filled in the casing is known (see Patent Literature 1).

### CITATION LIST

### Patent Literature

[Patent Literature 1] Japanese Patent Laid-Open No. 2021-150466

### SUMMARY OF THE INVENTION

### Technical Field

In semiconductor devices, casings filled with thermosetting resins are generally composed of a thermoplastic resin such as polyphenylene sulfide (PPS) or polybutylene terephthalate (PBT) and an inorganic filler. For casings including PPS as a material (hereinafter referred to as PPS casings) of these, delamination between a sealing material including a thermosetting resin such as an epoxy resin and the PPS casing is a problem.

### Solution to Problem

When delamination between the thermosetting resin and the PPS casing occurs, entry paths into the semiconductor device may be formed from the delaminated part for substances such as moisture and corrosive gases, which impair the performance of the members inside the semiconductor device. In particular, when partial delamination occurs between a sealing material and a PPS casing, problems may occur; for example, stress may concentrate at parts in which contact between the sealing material and the PPS casing is maintained without delamination.

As a result of diligent research, the present inventors have found that when the surface of a PPS casing in contact with a sealing material has a structure in which delamination from the sealing material can be suppressed, reliability decrease can be prevented. Thus, the present inventors have completed the present invention.

Specifically, according to one embodiment, the present invention relates to a semiconductor device including: a casing including an inorganic filler in a matrix including polyphenylene sulfide; a semiconductor element mounted on a laminated substrate; and a sealing material sealing the semiconductor element, wherein the inorganic filler is exposed from the matrix on a surface of the casing facing the sealing material.

In the semiconductor device, it is preferred that a content of the inorganic filler based on a total mass of the casing is 40 to 70% by mass, and an exposed area percentage of the inorganic filler is 10 to 60%.

In the semiconductor device, the inorganic filler is preferably a fibrous inorganic filler.

In the semiconductor device, the inorganic filler is preferably selected from a metal oxide or a metal nitride.

In the semiconductor device, the sealing material preferably includes a thermosetting resin selected from an epoxy resin, a maleimide resin, a cyanate resin, and an oxazine resin.

In the semiconductor device, the surface of the casing facing the sealing material is preferably an etched surface.

In the semiconductor device, the inorganic filler exposed is preferably in contact with the sealing material.

In the semiconductor device, a silane coupling agent layer is preferably formed on the surface of the casing facing the sealing material.

In the semiconductor device in which the silane coupling agent layer is formed, the silane coupling agent layer is preferably in contact with the sealing material.

According to another embodiment, the present invention relates to a method for manufacturing a semiconductor device, including steps of: manufacturing a casing including an inorganic filler in a matrix including polyphenylene sulfide; immersing the casing in an etchant to expose the inorganic filler from the matrix; arranging a semiconductor element mounted on a laminated substrate in the casing obtained by the exposing step; and filling the casing in which the semiconductor element is arranged, with a sealing material for sealing.

The method for manufacturing a semiconductor device preferably further includes a step of forming a silane coupling agent layer on a surface on which the inorganic filler is exposed, before the step of arranging the semiconductor element.

In the method for manufacturing a semiconductor device, the silane coupling agent is preferably a silane coupling agent including an epoxy group or an amino group.

### Advantageous Effect of Invention

According to the present invention, it is possible to provide a semiconductor device in which delamination between a PPS casing and a sealing material is suppressed and which has high reliability.

### BRIEF DESCRIPTION OF THE DRAWINGS

FIG. 1 is a conceptual cross-sectional view showing the cross-sectional structure of a semiconductor device according to the present invention.

FIG. 2 is a graph according to a Reference Example and shows the relationship between the etching time (hr) and the exposed area percentage (%) of silica when a resin composite substrate of PPS and silica is immersed in concentrated nitric acid at 80° C. to perform etching.

FIG. 3 is a graph according to Examples and shows the relationship between the silica exposed area percentage (%) of a resin composite substrate of PPS and silica and the adhesive strength (MPa) of the resin composite substrate of PPS to an epoxy resin.

### DESCRIPTION OF PREFERRED EMBODIMENTS

Embodiments of the present invention will be described below with reference to the drawings. However, the present invention is not limited by the embodiments described below.

According to one embodiment, the present invention relates to a semiconductor device. The semiconductor device according to this embodiment includes a casing including an inorganic filler in a matrix including polyphenylene sulfide; a semiconductor element mounted on a laminated substrate; and a sealing material sealing the semiconductor element, and the inorganic filler is exposed from the matrix including the polyphenylene sulfide on the surface of the casing facing the sealing material.

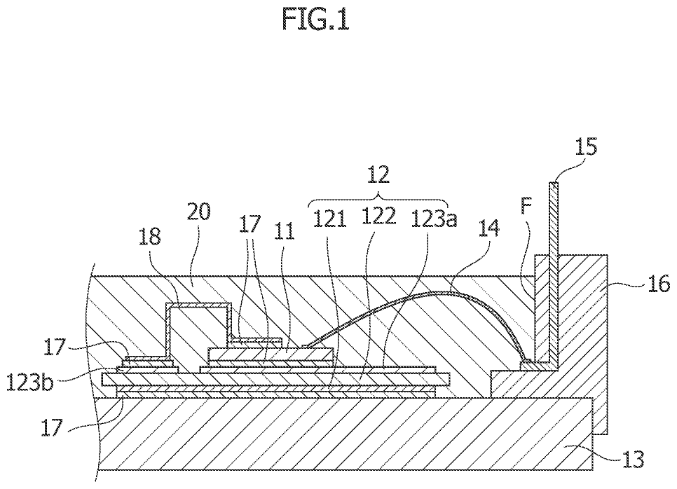

FIG. 1 is a conceptual cross-sectional view of a power semiconductor module that is one example of the semiconductor device according to this embodiment. The illustrated power semiconductor module has a laminated structure in which a semiconductor element 11 and a laminated substrate 12 are bonded on a heat sink 13 by a bonding layer 17. A casing 16 containing an external terminal 15 is adhered to the heat sink 13. Electrode of the semiconductor element 11 and the laminated substrate 12 are connected by a lead frame 18, which is an electrically conductive connecting member. The semiconductor element 11 and the external terminal 15 are connected by an aluminum wire 14. The space formed by the casing 16 and the heat sink 13 is filled with a sealing material 20 in contact with the semiconductor element 11, the laminated substrate 12, the lead frame 18, and the aluminum wire 14 that is an electrically conductive connecting member.

The semiconductor element 11 is a power chip such as an IGBT (Insulated Gate Bipolar Transistor) or a diode chip and may be a Si element or a wide gap semiconductor element such as a SiC element, a GaN element, a diamond element, or a ZnO element. These elements may be used in combination. For example, a hybrid module using a Si-IGBT and a SiC—SBD can be used. The number of mounted semiconductor elements may be one, and a plurality of semiconductor elements can also be mounted.

The laminated substrate 12 can be composed of an insulating substrate 122, a first electrically conductive plate 121 formed on one major surface of the insulating substrate 122, and second electrically conductive plates 123a and 123b formed on the other major surface. As the insulating substrate 122, a material that has excellent electrical insulating properties and thermal conductivity can be used. Examples of the material of the insulating substrate 122 include Al₂O₃, AlN, and SiN. Particularly in high withstand voltage applications, materials that achieve both electrical insulating properties and thermal conductivity are preferred, and AlN and SiN can be used, but the material of the insulating substrate 122 is not limited to these. As the first electrically conductive plate 121 and the second electrically conductive plates 123a and 123b, a metal material such as Cu or Al that has excellent workability can be used. The electrically conductive plates may be Cu or Al subjected to treatment such as Ni plating for the purpose of rust prevention and the like. Examples of the method for arranging the electrically conductive plates 121, 123a, and 123b on the insulating substrate 122 include a Direct Copper Bonding method or an Active Metal Brazing method. In the illustrated embodiment, the two second electrically conductive plates 123a and 123b are discontinuously provided on the insulating substrate 122, and one second electrically conductive plate 123a functions as an electrode bonded to the semiconductor element 11, and the other second electrically conductive plate 123b functions as an electrode connected to the lead frame 18.

The lead frame 18 is an electrically conductive connecting member connecting the semiconductor element 11 to the second electrically conductive plate 123b and the like. Specifically, the lead frame 18 is bonded to a front surface electrode 11a opposite to a back surface electrode 11b in contact with the laminated substrate 12, by the bonding layer 17 such as a solder material. The lead frame 18 is also bonded to a wiring portion such as the second electrically conductive plate 123b by the bonding layer 17 such as a solder material. The lead frame 18 may be a metal such as copper or an alloy including copper. A Ni or Ni alloy layer or a Cr or Cr alloy layer may be formed on the surface of the lead frame 18 by a plating method or the like. In this case, the film thickness of the Ni or Ni alloy layer or the Cr or Cr alloy layer can be about not greater than 20 μm. The lead frame may be connected to an extraction terminal (not illustrated).

As the heat sink 13, a metal such as copper or aluminum that has excellent thermal conductivity is used. For corrosion prevention, the heat sink 13 can also be coated with Ni or an Ni alloy. The heat sink may be a cooler having the function of water cooling, air cooling, or the like. A semiconductor device in a mode in which the casing 16 is attached to the laminated substrate 12, and the heat sink 13 is not attached to the casing 16, may also be possible.

The bonding layer 17 can be formed using lead-free solder. For example, Sn—Ag—Cu, Sn—Sb, Sn—Sb—Ag, Sn—Cu, Sn—Sb—Ag—Cu, Sn—Cu—Ni, or Sn—Ag-based solder can be used, but the lead-free solder is not limited to these. Alternatively, the bonding layer can also be formed using a connecting material including fine metal particles, such as a sintered body of silver nanoparticles.

The casing 16 is a molded product including an inorganic filler in a matrix including polyphenylene sulfide (PPS) and may be generally molded integrally with the external terminal 15 made of metal. The matrix is a resin for surrounding the particles of the inorganic filler, retaining the particles, and being in the form of a casing and can be an insulating resin. PPS is the main component of the matrix and can be not less than 50% by mass of the total mass of the matrix and can also be not less than 60% by mass, not less than 80% by mass, not less than 90% by mass, or not less than 95% by mass. In addition to PPS, an epoxy resin or a phenolic resin may be added to the matrix, for example, in an amount of about not greater than 10% by mass. The casing 16 may optionally include about less than 5% by mass of usual additives based on the total mass of the casing, in addition to the matrix and the inorganic filler, and the additives may include a flame retardant and a plasticizer.

The casing 16 generally has a shape in which it surrounds the side surface of the semiconductor element 11, and the laminated substrate 12 and the electrically conductive connecting members such as the lead frame and the wire bonded to the semiconductor element 11. The bottom of the casing 16 is open and may be frame-shaped, and the bottom surface of the frame portion may be bonded to the heat sink 13 or the laminated substrate 12 via a bonding material. The outer surface of the casing 16 constitutes part of the outer surface of the semiconductor device. Here, the side surface of the semiconductor element 11 refers to a surface perpendicular to the front surface electrode 11a and the back surface electrode 11b. The inner surface of the casing 16 includes a surface facing the sealing material 20. The surface facing the sealing material 20 refers to a surface in direct contact with the sealing material 20 or adjacent to the sealing material 20 via a surface treatment layer such as a silane coupling agent layer between the casing 16 and the sealing material 20. As used herein, the surface of the casing 16 facing the sealing material 20 is also referred to as a sealing material-facing surface F. In the casing 16, the sealing material-facing surface F may be generally the inner side surface of the casing 16.

PPS is less likely to form a bond with another organic matter or inorganic matter and also less likely to be bonded to a thermosetting resin such as an epoxy resin, and the adhesiveness between PPS and a thermosetting resin such as an epoxy resin (sealing material) is not high, as described later. Therefore, when the inorganic filler is in a state of being covered with PPS, delamination may occur between the casing and the sealing material. On the other hand, the adhesion between the inorganic filler and a thermosetting resin such as an epoxy resin is high. Therefore, the inorganic filler is preferably exposed from the matrix including PPS on the entire sealing material-facing surface F. If partial delamination between the sealing material 20 and the casing 16 occurs on the sealing material-facing surface F, stress concentration on the portion without delamination is a concern.

The PPS should have a repeating unit represented by the following formula (1) and may include only the repeating unit.

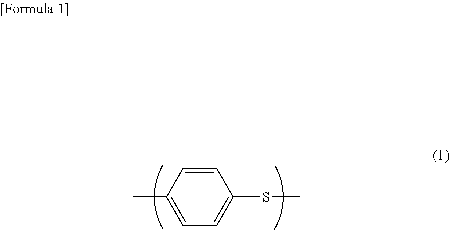

Therefore, the PPS may be linear PPS or crosslinked PPS.

The casing is preferably insulating, and therefore, the inorganic filler may be a metal oxide or a metal nitride and can be selected from, for example, fused silica, silica (silicon oxide), alumina, aluminum hydroxide, titania, zirconia, aluminum nitride, talc, clay, mica, and glass fibers but is not limited to these. In particular, metal oxides such as silica and alumina having an OH group on the surface are preferred because, for example, the epoxy group of the epoxy resin of the sealing material and the OH group are easily bonded, and therefore the metal oxides have adhesive force. Two or more different inorganic fillers can also be used in combination.

The inorganic filler is preferably fibrous. Here, the fibrous shape may be a shape that has an aspect ratio (length/diameter) of generally 10 to 100 and can supplement the strength of the resin. The fibrous shape may be sometimes referred to as a needle shape or a rod shape. For the inorganic filler, one having an average particle diameter of about 10 μm to 100 μm can be used. The average particle diameter of the fibrous inorganic filler refers to the average major axis. The average value may be a value obtained by a laser diffraction type particle size distribution meter.

The content (filling rate) of the inorganic filler, when the total mass of the materials constituting the casing 16 is 100%, may be, for example, 40 to 70% by mass or 45 to 60% by mass, and the remainder may be the matrix. Pellets or compounds including as main components a matrix including PPS and an inorganic filler are commercially available, and those skilled in the art can select pellets or a compound conforming to the specifications of the casing of the semiconductor device.

In the casing 16 that is a molded product, generally, the inorganic filler is substantially uniformly dispersed in a matrix mainly composed of a resin of PPS. On the casing surface immediately after molding, the inorganic filler is covered with the matrix of PPS, and usually the inorganic filler is hardly exposed on the surface.

In the casing 16 according to the present invention, the inorganic filler is exposed at least on the sealing material-facing surface F. The inorganic filler being exposed means that the inorganic filler is present in a state in which the surface is not covered with the PPS. The exposure of the inorganic filler can be confirmed, for example, by an optical digital microscope because the reflectance of the matrix and that of the inorganic filler differ. As used herein, for the purpose of quantifying the degree of the exposure of the inorganic filler on the sealing material-facing surface F, “exposed area percentage” is used. The exposed area percentage refers to a white area percentage (%) per the observation field of view of a digital microscope by binarization under certain conditions. More specifically, the exposed area percentage is a white area percentage when binarization is performed on an image having an evaluation area of 500 μm×500 μm obtained by observing the sealing material-facing surface F of the casing 16 at 50× magnification using a digital microscope, for example, under conditions in which the brightness is adjusted between 0.0 (darkest value) and 1.0 (brightest value), and the threshold is 0.5, for obtaining a black and white binary image. When binarization is performed under these conditions, the PPS is represented by black, and the inorganic filler is represented by white, and the proportion of each when the sealing material-facing surface F is evaluated on a two-dimensional plane can be calculated. The exposed area percentage of a casing 16 can be the average value of measurement results in a plurality of locations at the site of one casing to which the greatest potential stress is applied, although it depends on the total area of the sealing material-facing surface F of the casing 16. Although it depends on the shape of the casing, the site to which the greatest potential stress is applied may be, for example, a longitudinal end when the casing is seen in a planar view. The plurality of locations may be, for example, 5 to 10 locations.

When the exposed area percentage is greater than 0%, the improvement in adhesion to the sealing material can be promoted compared with a case having an exposed area percentage of 0%. In particular, the exposed area percentage is preferably 10 to 60%, and more preferably 20 to 50%. When the exposed area percentage is in the range of 10 to 60%, the adhesive strength between the casing and the sealing material can be twice or more compared with the case in which the exposed area percentage is 0%. When the exposed area percentage is in the range of 20 to 50%, the adhesive strength between the casing and the sealing material can be four times or more compared with the case in which the exposed area percentage is 0%.

The sealing material-facing surface F on which the inorganic filler is exposed is, for example, preferably a surface formed by chemical treatment, and particularly preferably an etched surface. The specific conditions of etching will be described in detail for a method for manufacturing a semiconductor device, and wet etching (chemical etching) is preferred. A surface subjected to chemical treatment may be preferred in that compared with a surface subjected to physical treatment such as blasting, there is no possibility that mechanical force is applied at the treatment stage, and therefore, the inorganic filler can be effectively exposed without decreasing the brittleness of the PPS. Etching may be preferred because by etching, the matrix around the particles of the inorganic filler is depressed, and the particles of the inorganic filler protrude, and therefore, the adhesiveness to the sealing material also improves.

A silane coupling agent layer may be optionally formed on the sealing material-facing surface F of the casing 16. The silane coupling agent can be interposed between the exposed inorganic filler and the sealing material 20 to form bonds like covalent bonds with both and increase the adhesiveness between the casing 16 and the sealing material 20 more. As the silane coupling agent, a silane coupling agent including an epoxy group, an amino group, or both of them is preferably used. Specific examples of preferred silane coupling agents include, but are not limited to, 2-(3,4-epoxycyclohexyl)ethyltrimethoxysilane, 3-glycidoxypropylmethyldimethoxysilane, 3-glycidoxypropyltrimethoxysilane, 3-glycidoxypropylmethyldiethoxysilane, 3-glycidoxypropyltriethoxysilane, N-2-(aminoethyl)-3-aminopropylmethyldimethoxysilane, N-2-(aminoethyl)-3-aminopropyltrimethoxysilane, 3-aminopropyltrimethoxysilane, and 3-aminopropyltriethoxysilane.

The formation thickness of the silane coupling agent layer can be, for example, not less than about 1 μm and not greater than about 50 μm, and is preferably not less than about 1 μm and about not greater than about 20 μm, in terms of thickness after drying. On the sealing material-facing surface F of the casing 16 after the formation of the silane coupling agent layer, the exposed inorganic filler and the PPS are covered with the silane coupling agent layer. In a state in which the semiconductor device is manufactured, a mode in which the silane coupling agent layer is mainly in contact with the sealing material 20 is provided. The silane coupling agent forms chemical bonds with both the inorganic filler and the sealing material 20, and thus, delamination between the casing 16 and the sealing material 20 can be prevented. However, a mode in which the inorganic filler is partially exposed from the silane coupling agent layer, and the inorganic filler is in contact with the sealing material 20, is also possible. Even in this case, the adhesiveness between the casing 16 and the sealing material 20 can be improved compared with a case in which the sealing material 20 is in contact with only the PPS.

On the surfaces of the casing 16 other than the sealing material-facing surface F, the inorganic filler may or may not be exposed from the matrix of PPS. This can be appropriately selected by those skilled in the art from the viewpoint of convenience in the method for manufacturing a semiconductor device described later.

The sealing material 20 may be a thermosetting resin cured product obtained by curing a thermosetting resin composition that includes a thermosetting base resin and an inorganic filler and may optionally include a curing agent, a curing accelerator, and additives.

The thermosetting base resin is not particularly limited, and examples thereof can include epoxy resins, phenolic resins, maleimide resins, cyanate resins, and oxazine resins. In particular, epoxy resins having at least two or more epoxy groups in one molecule are particularly preferred because of high dimensional stability, high water resistance and chemical resistance, and high electrical insulating properties. Specifically, an aliphatic epoxy resin, an alicyclic epoxy resin, or a mixture thereof is preferably used. As the sealing resin, thermosetting resins are preferred because heat resistance and high insulating properties are requirements, and in particular, epoxy resins having high elasticity are preferred.

The aliphatic epoxy resin refers to an epoxy compound in which carbon to which an epoxy group is directly bonded is carbon constituting an aliphatic hydrocarbon. Therefore, even compounds in which an aromatic ring is included in the main skeleton are classified as aliphatic epoxy resins when they satisfy the condition. Examples of the aliphatic epoxy resin include, but are not limited to, bisphenol A type epoxy resins, bisphenol F type epoxy resins, bisphenol AD type epoxy resins, biphenyl type epoxy resins, naphthalene type epoxy resins, cresol novolac type epoxy resins, and tri- or higher functional polyfunctional epoxy resins. These can be used alone, or two or more types thereof can be mixed and used. Naphthalene type epoxy resins and tri- or higher functional polyfunctional epoxy resins have high glass transition temperature and are therefore also referred to as highly heat-resistant epoxy resins. By including these highly heat-resistant epoxy resins, the heat resistance can be improved.

The alicyclic epoxy resin refers to an epoxy compound in which two carbon atoms constituting an epoxy group constitute an alicyclic compound. Examples of the alicyclic epoxy resin include, but are not limited to, monofunctional epoxy resins, bifunctional epoxy resins, and tri- or higher functional polyfunctional epoxy resins. The alicyclic epoxy resin can also be used singly, or two or more different alicyclic epoxy resins can be mixed and used. When an alicyclic epoxy resin is mixed with an acid anhydride curing agent and is cured, the glass transition temperature increases, and therefore, when an alicyclic epoxy resin is mixed with an aliphatic epoxy resin for use, heat resistance can be promoted.

The thermosetting base resin used in the sealing material 20 may be a mixture of the aliphatic epoxy resin and alicyclic epoxy resin. The mixing ratio when the aliphatic epoxy resin and alicyclic epoxy resin are mixed may be freely chosen, and the mass ratio between the aliphatic epoxy resin and the alicyclic epoxy resin may be about 2:8 to 8:2 but may be about 3:7 to 7:3, and is not limited to a particular mass ratio. In a preferred mode, the thermosetting base resin used in the sealing material 20 is a mixture in which the mass ratio between a bisphenol A type epoxy resin and an alicyclic epoxy resin is 1:1 to 1:4.

The inorganic filler may be a metal oxide or a metal nitride, and examples of the inorganic filler include, but are not limited to, fused silica, silica (silicon dioxide), alumina, aluminum hydroxide, titania, zirconia, aluminum nitride, talc, clay, mica, and glass fibers. These inorganic fillers can increase the thermal conductivity of the sealing material 20 and reduce the thermal expansion coefficient. These inorganic fillers may be used singly, but two or more of these inorganic fillers may be mixed and used. The inorganic filler may be a microfiller or a nanofiller, and two or more inorganic fillers in which the particle diameter and/or the type are different can also be mixed and used. In particular, an inorganic filler having an average particle diameter of about 0.2 to 20 μm is preferably used. The amount of the inorganic filler added in the sealing material 20 is preferably 100 to 600 parts by mass, and further preferably 200 to 400 parts by mass, when the total mass of the thermosetting base resin and the curing agent that can be optionally included is 100 parts by mass. When the amount of the inorganic filler blended is less than 100 parts by mass, the thermal expansion coefficient of the sealing material 20 may increase, easily causing delamination and cracking. When the amount blended is more than 600 parts by mass, the viscosity of the composition may increase, reducing extrudability.

The thermosetting resin composition constituting the sealing material 20 may include a curing agent as an optional component. The curing agent is not particularly limited as long as it can react with the thermosetting base resin, preferably an epoxy base resin, to cure it. An acid anhydride curing agent is preferably used. Examples of the acid anhydride curing agent include aromatic acid anhydrides, specifically phthalic anhydride, pyromellitic anhydride, and trimellitic anhydride. Alternatively, examples of the acid anhydride curing agent can include cycloaliphatic acid anhydrides, specifically tetrahydrophthalic anhydride, methyltetrahydrophthalic anhydride, hexahydrophthalic anhydride, methylhexahydrophthalic anhydride, and methylnadic anhydride, or aliphatic acid anhydrides, specifically succinic anhydride, polyadipic anhydride, polysebacic anhydride, and polyazelaic anhydride. The amount of the curing agent blended is preferably not less than about 50 parts by mass and not greater than about 170 parts by mass, more preferably not less than about 80 parts by mass and not greater than about 150 parts by mass, based on 100 parts by mass of the thermosetting resin (epoxy resin) base. When the amount of the curing agent blended is less than 50 parts by mass, the glass transition temperature may decrease because of insufficient crosslinking. When the amount of the curing agent blended is more than 170 parts by mass, the moisture resistance, the high thermal deformation temperature, and the heat-resistant stability may decrease. When, as the thermosetting base resin, a bisphenol A type epoxy resin is used alone, or a mixture of a bisphenol A type epoxy resin and a previously shown highly heat-resistant epoxy resin is used, using no curing agent may be preferred because heat resistance improves. The blending ratio of the highly heat-resistant epoxy resin may be, for example, not less than 10% by mass and not greater than 50% by mass, and more preferably not less than 10% and not greater than 25% by mass, when the total mass of the thermosetting base resin is 100%. This range is preferred because the heat resistance improves, and the viscosity does not increase.

A curing accelerator as an optional component can be further added to the thermosetting resin composition constituting the sealing material 20. As the curing accelerator, imidazole or a derivative thereof, a tertiary amine, a borate, a Lewis acid, an organometallic compound, an organic acid metal salt, or the like can be appropriately blended. The amount of the curing accelerator added is preferably not less than 0.01 parts by mass and not greater than 50 parts by mass, more preferably not less than 0.1 parts by mass and not greater than 20 parts by mass, based on 100 parts by mass of the thermosetting base resin.

The thermosetting resin composition constituting the sealing material 20 may also include optional additives in a range that does not impair its characteristics. Examples of the additives include, but are not limited to, flame retardants, pigments for coloring the resin, and plasticizers and silicon elastomers for improving cracking resistance. Those skilled in the art can appropriately determine these optional components and the amounts of the optional components to be added, according to the specifications required of the semiconductor device and/or the sealing material.

The sealing material 20 may have a one-layer configuration including one type of resin having the composition illustrated above, or a configuration including two or more layers. The sealing material 20 may further include a layer of a thermoplastic resin or a silicone rubber on one or more thermosetting resin layers.

In the semiconductor device according to this embodiment, the inorganic filler is exposed from the PPS matrix on the sealing material-facing surface F of the casing. Therefore, adhesion between the casing and the resin constituting the sealing material can be increased, and penetration of moisture and gas can be prevented. Furthermore, local stress concentration due to partial delamination between the casing and the sealing material can also be prevented. Conventional casing surfaces are covered with PPS, and the inorganic filler is present inside, and therefore, the conventional casing surfaces have little polarity, and increasing the surface area by roughening or the like has only been known. It is not intended to be bound by theory, but according to the present invention, by exposing an inorganic filler having a polar group from the matrix of PPS, it is possible to polarize the casing surface and improve the adhesion to the sealing material.

The present invention has been described by showing the cross-sectional structure of a particular module in FIG. 1, but the configurations of the laminated substrate, the semiconductor element, the electrically conductive connecting member, and the external terminal are not limited to the illustrated forms. The relationship between the sealing material and the casing surface should satisfy the above. For example, the electrically conductive connecting member may be only one of a lead frame, a wire, and an implant pin, or may include two or more of these. For example, it is also possible to further include a printed board connected to the front surface electrode of the semiconductor element by an implant pin and insulate and seal the printed board. For example, it is also possible to form a primer layer on the surfaces of the members in contact with the sealing material, such as the semiconductor element, the laminated substrate, and the electrically conductive connecting member.

Next, a semiconductor device according to one embodiment of the present invention will be described from the viewpoint of a manufacturing method. A method for manufacturing a semiconductor device includes the following steps:
(1) the step of manufacturing a casing including an inorganic filler in a matrix including polyphenylene sulfide;
(2) the step of immersing the casing in an etchant to expose the inorganic filler from the matrix;
(3) the step of arranging a semiconductor element mounted on a laminated substrate in the casing obtained by the exposing step; and
(4) the step of filling the casing, in which the semiconductor element is arranged, with a sealing material for sealing.

The method for manufacturing a semiconductor device may optionally include a step of forming a silane coupling agent layer on a surface on which the inorganic filler is exposed, after the step (2) and before the step (3). Each of the steps will be described below.

(1) Casing Manufacturing Step

In the first step, a casing material including PPS and an inorganic filler is molded to manufacture a casing including the inorganic filler in a matrix including polyphenylene sulfide. As one example, the manufacture of the casing can be carried out by manufacturing a mold conforming to the specifications of the casing and performing injection molding, by a typical method. The composition ratio of PPS and the inorganic filler, and other additives may be as previously described. Generally, injection molding can be performed with a metal member such as an external terminal integrated with the casing. In addition to injection molding, extrusion, compression molding, blow molding, vacuum and pressure forming, and shaping using a 3D printer are also possible.

(2) Etching Step

In the second step, the casing obtained in the first step is immersed in an etchant to etch the casing surface (chemical etching). When a member to be protected from the etchant is included, such as when a metal member such as an external terminal is integrated with the casing obtained in the first step, the protection part can be masked before introduction into the etchant. Surfaces other than a surface to face a sealing material, such as the outer surface of the casing, can also be masked.

The etchant should be a liquid with which the PPS etching rate Vₚₚₛ and the inorganic filler etching rate Vᵢ satisfy the following relationship: Vₚₚₛ>Vᵢ. For example, concentrated nitric acid, 50% chromic acid, 5% hypochlorous acid, concentrated sulfuric acid, or the like can be used. In particular, it is preferred that concentrated nitric acid be used as the etchant, and that the casing be immersed in the etchant at about 80 to 90° C. over about 10 to 60 hours to perform etching. The relationship between the etching conditions for the casing material having a particular composition and the exposed area percentage of the inorganic filler can be obtained by preliminary experimentation to determine the composition of the etchant, the temperature, and the treatment time.

After the casing is immersed in the etchant for a predetermined time, the casing is washed in water and dried, and optionally, the masking is removed. Thus, the casing in which the inorganic filler is exposed from the matrix of PPS at least on the entire surface of the sealing material-facing surface F can be obtained.

As an optional step after the second step, the step of forming a silane coupling agent layer on the surface (sealing material-facing surface F) of the casing 16 on which the inorganic filler is exposed can be carried out. The formation of the silane coupling agent layer can be carried out by application, spraying, or the like. In order to obtain the desired layer thickness of the silane coupling agent layer, the relationship of the concentration of the silane coupling agent solution and the spraying time with the layer thickness after drying can be obtained by a preliminary experiment to determine the conditions for applying or spraying the silane coupling agent solution. After application, the silane coupling agent solution is preferably sufficiently dried over 5 to 24 hours at a temperature necessary according to the specifications of the silane coupling agent used.

(3) Arrangement and Assembly Step

In the third step, a semiconductor device is assembled using the casing obtained in the second step or optionally in the step of forming a silane coupling agent layer. A heat sink 13, a laminated substrate 12, and a semiconductor element 11 are bonded by a usual method. Then, the casing 16 is attached and fixed to the heat sink 13 using a resin or the like. Subsequently, the bonding of a lead frame 18, and wire bonding with an aluminum wire 14 are performed. Depending on the configuration of the semiconductor device, the bonding of an implant pin and a printed board can also be optionally performed. The step of forming a primer layer on the surfaces of the members to be in contact with a sealing material in the next step, for example, the semiconductor element, the laminated substrate, and the electrically conductive connecting members, can also be performed. It is not preferred to provide the primer layer on the casing surface.

(4) Sealing Step

In the fourth step, the assembled members are insulated and sealed according to a typical method. Specifically, a thermosetting resin composition for constructing a sealing material 20 is injected into the casing 16 and is heated and cured. The step of heating and curing can be, for example, two-stage curing. When an epoxy resin is used as the thermosetting base resin, the thermosetting resin composition is heated at 90 to 120° C. for 1 to 2 hours to a semi-cured state. Subsequently, heating can be further carried out at 175 to 185° C. over 1 to 2 hours (full curing). However, the curing condition is not limited to particular temperatures and times, and the two-stage curing may not be necessary. In a semiconductor device in which a sealing material optionally includes two or more layers, two or more sealing layers can be appropriately formed.

According to the method for manufacturing a semiconductor device according to this embodiment, the inorganic filler can be exposed from the matrix of PPS for constructing the casing to provide a configuration in which the inorganic filler and the sealing material can be brought into contact with each other. Alternatively, a configuration in which the inorganic filler and the silane coupling agent layer can be brought into contact with each other can be optionally provided. Thus, it is possible to manufacture a semiconductor device in which the adhesion between a casing and a sealing material is improved compared with conventional semiconductor devices in which PPS constructing a casing is mainly in contact with a sealing material.

The present invention will be described in more detail below by giving Examples of the present invention. However, the present invention is not limited to the scope of the following Examples.

### [REFERENCE EXAMPLE] STUDY OF CONDITIONS FOR EXPOSING INORGANIC FILLER

In the manufacture of casings in which an inorganic filler was exposed from a matrix including PPS, conditions for exposing the inorganic filler by chemical etching were studied. Resin composite substrates (10×10×1 (mm)) of a matrix including PPS and silica, which was an inorganic filler, simulating a casing were manufactured. As the matrix, a PPS resin TORELINAA610 (Toray Industries Inc.) was used. A substrate in which the filling rate of silica was 50% by mass, and a substrate in which the filling rate of silica was 70% by mass were obtained by injection molding. When the surfaces were observed by a digital microscope (manufactured by KEYENCE CORPORATION, model VHX-7000) before chemical etching, no exposure of silica was seen for either.

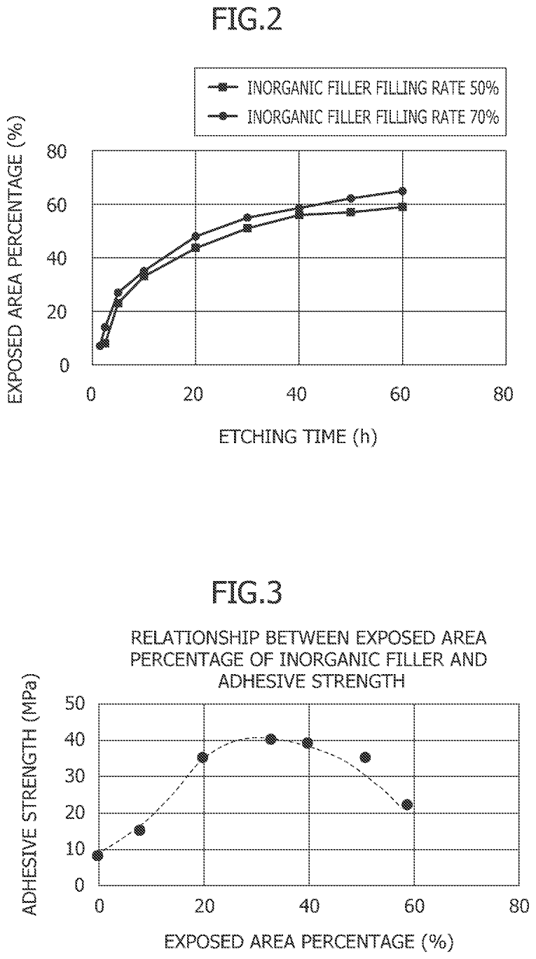

These substrates were immersed in concentrated nitric acid at 80° C. to perform etching. The definition of the exposed area percentage of the inorganic filler is as previously shown. The relationship between the etching time (hr) and the exposed area percentage (%) of the inorganic filler is shown in FIG. 2. From FIG. 2, it was confirmed that for both the substrate in which the filling rate of the inorganic filler was 50% by mass, and the substrate in which the filling rate of the inorganic filler was 70% by mass, the exposed area percentage was controllable in the range of about 10 to 65% by controlling the etching time using concentrated nitric acid at 80° C.

### Examples

### (1) Evaluation of Exposed Area Percentage and Inorganic Filler Filling Rate and Adhesive Strength

In order to evaluate the delamination strength (shear strength) between the casing and the sealing material in the power semiconductor module shown in FIG. 1, a pudding cup-shear test was performed. A resin composite substrate of a matrix including PPS and silica, which was an inorganic filler, was etched to expose the silica to provide a substrate for the pudding cup-shear test. For the etching, concentrated nitric acid at 93° C. was used. An epoxy resin composition usable as a sealing material was molded on this substrate to a bottom surface diameter of 3.6 mm, an upper surface diameter of 3.0 mm, and a height of 3.0 mm and subjected to a thermal curing reaction at 100 to 180° C. over 3 hours to obtain a test piece of an epoxy resin cured product molded on the substrate. The specific composition of the epoxy resin composition was as follows. As the epoxy base resin, an epoxy resin ME-276 (manufactured by Pelnox, Ltd.) was used, and 121 parts by mass of MV-138 (manufactured by Pelnox, Ltd.) as an acid anhydride curing agent was added based on 100 parts by mass of the epoxy base resin. For the inorganic filler, fibrous silica having an average particle diameter of 10 μm (manufactured by Nippon Electric Glass Co., Ltd.) was used, and 270 parts by mass of the fibrous silica was added when the total mass of the base of the epoxy resin and the curing agent was 100 parts by mass.

For the measurement of the shear strength, a force gauge (load measuring instrument: ZTA-1000N manufactured by IMADA) was used. For the measurement conditions, the epoxy resin cured product portion was pressed parallel to the adhering surface at a rate (strain rate) of 0.2 mm/s, and the strength when the epoxy resin cured product/resin composite substrate interface was delaminated and breakage occurred was taken as the adhesive strength.

The filling rate (% by mass) of the inorganic filler (silica), the exposed area percentage (%) of the inorganic filler, the etching time condition (hr) for the exposure of the inorganic filler, and the adhesive strength (MPa) in Examples 1 to 9 and Comparative Example 1 are shown in Table 1. The relationship between the exposed area percentage (%) and the adhesive strength (MPa) is shown in FIG. 3.

TABLE 1

| | | | | | | | | | | Comparative |
|---|---|---|---|---|---|---|---|---|---|---|
| | Examples | | | | | | | | | Example |
| | 1 | 2 | 3 | 4 | 5 | 6 | 7 | 8 | 9 | 1 |
| Filling rate (% by mass) | 50 | 50 | 50 | 50 | 50 | 50 | 40 | 60 | 70 | 50 |
| Etching time (hr) | 2.5 | 5 | 10 | 18 | 30 | 60 | 12 | 8 | 7.5 | None |
| Exposed area percentage | 8 | 23 | 33 | 40 | 51 | 59 | 30 | 30 | 30 | 0 |
| (%) | | | | | | | | | | |
| Adhesive strength (Mpa) | 15 | 35 | 40 | 39 | 35 | 22 | 35 | 43 | 44 | 8 |

The adhesive strength between the casing and the sealing material improved in all of Examples 1 to 9, compared with the Comparative Example in which the exposed area percentage of the inorganic filler was 0%. The adhesive strength between the casing and the sealing material should be about 15 MPa and is preferably not less than 20 MPa, and more preferably not less than 35 MPa. From this, it can be said that the exposed area percentage of the inorganic filler at which the adhesive strength between the casing and the sealing material can be improved is about 10 to 60%, the preferred exposed area percentage is 12 to 60%, and the particularly preferred exposed area percentage is about 20 to 50%.

### (2) Evaluation of Silane Coupling Agent Layer and Adhesive Strength

Next, a silane coupling agent layer was formed on a casing surface in which the filling rate was 50% by mass and the exposed area percentage of the inorganic filler (silica) was 50%, and the adhesive strength was evaluated. A silane coupling agent manufactured by Shin-Etsu Chemical Co., Ltd., was used, and water was added to dilute the silane coupling agent two to five times. Then, the diluted silane coupling agent was stirred until it was uniform. Then, the silane coupling agent after dilution and stirring was sprayed on the inorganic filler-exposed surface and dried at 120° C. over 24 hours. The adhesive strength was measured with the type of the silane coupling agent and the changed layer thickness. The epoxy resin composition used for the measurement of the adhesive strength, and the adhesive strength measurement conditions, were the same as the previous (1). The differences in adhesive strength by the type of the silane coupling agent are shown in Table 2. The layer thickness after drying was 5 μm for all silane coupling agents. The differences in adhesive strength by the differences in layer thickness when the silane coupling agent is an epoxy KBM-403 are shown in Table 3. In both Tables 2 and 3, the exposed area percentage represents the exposed area percentage of the inorganic filler before silane coupling agent application.

TABLE 2

| | Example X1 | Example X2 | Example X3 |
|---|---|---|---|
| Silane coupling agent | Epoxy | Epoxy | Amino |
| | KBM-403 | KBE-403 | KBM-602 |
| Exposed area percentage (%) | 50 | 50 | 50 |
| Adhesive strength (Mpa) | 45 | 52 | 39 |

TABLE 3

| | Example | Example | Example | Example |
|---|---|---|---|---|
| | Y1 | Y2 | Y3 | Y4 |
| Thickness (μm) | 1 | 5 | 20 | 50 |
| Exposed area percentage | 50 | 50 | 50 | 50 |
| (%) | | | | |
| Adhesive strength (Mpa) | 45 | 52 | 44 | 34 |

When the amino group-containing silane coupling agent and the epoxy group-containing silane coupling agents were used as the silane coupling agent, improvement in the adhesive strength was seen. When the layer thickness was 1 to 20 μm, there was great improvement in adhesive strength.

### (3) Evaluation of Exposure Method and Adhesive Strength

For a casing in which chemical etching was used as a method for exposing an inorganic filler, and a casing in which blasting was used as a method for exposing an inorganic filler, the adhesion between a substrate simulating a PPS casing filled with 50% by mass of silica and an epoxy resin was examined using the same materials as in (1). In Example Z1 using chemical etching, for the method for exposing the inorganic filler, the substrate was heated in concentrated nitric acid at 80° C. over 30 hours. On the other hand, in Example Z2 using blasting, one surface of the substrate was air-blasted. As the apparatus for air blasting, a gravity type SGK-4LD-401 and a nozzle orifice diameter ø of 9 mm were used, and the working pressure was 0.5 MPa. As the abrasive, POLYEXTRA (low hardness) Mohs hardness 3 was used. In both methods, the treatment was performed with the aim of achieving an exposed area percentage of 30%. The epoxy resin composition used for the measurement of the adhesive strength, and the adhesive strength measurement conditions were the same as in the previous (1).

In Example Z1 using chemical etching, when an exposed area percentage 30% of was achieved, the silica, which was the inorganic filler, was exposed from the matrix including PPS, and the adhesive strength was 40 MPa. In Example Z2 using blasting, at an exposed area percentage of 30%, the adhesive strength was about 20 MPa, and necessary adhesive strength was achieved. It was shown that when blasting was used, there were local parts in which the silica was not completely exposed, and when chemical etching was used, more uniform roughening was performed by batch treatment, and therefore, higher adhesive strength was achieved.

From the above, it was confirmed that in both methods of chemical etching and blasting, the adhesive strength improved by exposing the inorganic filler from the matrix, and from the viewpoint of improvement, chemical etching was more advantageous and more preferred.

### REFERENCE SIGNS LIST

11: semiconductor element, 12: laminated substrate, 121: first electrically conductive plate, 122: insulating substrate, 123a, 123b: second electrically conductive plate, 13: heat sink, 14: aluminum wire, 15: external terminal, 16: casing, 17: bonding layer, 18: lead frame, 20: sealing layer, F: sealing material-facing surface

What is claimed is:

1. A semiconductor device comprising:
a casing comprising an inorganic filler in a matrix comprising polyphenylene sulfide;
a semiconductor element mounted on a laminated substrate; and
a sealing material sealing the semiconductor element,
wherein the inorganic filler is exposed from the matrix on a surface of the casing facing the sealing material.

2. The semiconductor device according to claim 1, wherein a content of the inorganic filler based on a total mass of the casing is 40 to 70% by mass, and an exposed area percentage of the inorganic filler is 10 to 60%.

3. The semiconductor device according to claim 1, wherein the inorganic filler is a fibrous inorganic filler.

4. The semiconductor device according to claim 1, wherein the inorganic filler is selected from a metal oxide or a metal nitride.

5. The semiconductor device according to claim 1, wherein the sealing material comprises a thermosetting resin selected from an epoxy resin, a maleimide resin, a cyanate resin, and an oxazine resin.

6. The semiconductor device according to claim 1, wherein the surface of the casing facing the sealing material is an etched surface.

7. The semiconductor device according to claim 1, wherein the inorganic filler exposed is in contact with the sealing material.

8. The semiconductor device according to claim 1, wherein a silane coupling agent layer is formed on the surface of the casing facing the sealing material.

9. The semiconductor device according to claim 8, wherein the silane coupling agent layer is in contact with the sealing material.

10. A method for manufacturing a semiconductor device, comprising steps of:
manufacturing a casing comprising an inorganic filler in a matrix comprising polyphenylene sulfide;
immersing the casing in an etchant to expose the inorganic filler from the matrix;
arranging a semiconductor element mounted on a laminated substrate in the casing obtained by the exposing step; and
filling the casing in which the semiconductor element is arranged, with a sealing material for sealing.

11. The method according to claim 10, further comprising a step of forming a silane coupling agent layer on a surface on which the inorganic filler is exposed, before the step of arranging the semiconductor element.

12. The method according to claim 11, wherein the silane coupling agent is a silane coupling agent comprising an epoxy group or an amino group.
